(19) United States
(12) Patent Application Publication
(10) Pub. No.: US 2025/0113740 A1
(43) Pub. Date: Apr. 3, 2025

(54) MAGNETIZED ROTARY ELEMENT, MAGNETORESISTIVE ELEMENT, AND MAGNETIC MEMORY

(71) Applicant: TDK CORPORATION, Tokyo (JP)

(72) Inventors: Takuya ASHIDA, Tokyo (JP); Tomoyuki SASAKI, Tokyo (JP)

(73) Assignee: TDK CORPORATION, Tokyo (JP)

(21) Appl. No.: 18/729,008

(22) PCT Filed: Feb. 25, 2022
(86) PCT No.: PCT/JP2022/007832

§ 371 Date: Jul. 15, 2024

(51) Int. Cl. H10N 50/10; G11C 11/16; H10N 50/85

(52) U.S. Cl. CPC H10N 50/10; G11C 11/161; G11C 11/1673; G11C 11/1675; H10N 50/85

(57) ABSTRACT

This magnetized rotary element includes a spin-orbit torque wiring and a first ferromagnetic layer connected to the spin-orbit torque wiring, wherein the spin-orbit torque wiring includes a topological insulator in which electrical conductors are dispersed.

### TECHNICAL FIELD

The present invention relates to a magnetized rotary element, a magnetoresistive element, and a magnetic memory.

### BACKGROUND ART

A giant magnetoresistance (GMR) element including a multilayer film of a ferromagnetic layer and a nonmagnetic layer and a tunnel magnetoresistance (TMR) element using an insulating layer (a tunnel barrier layer or a barrier layer) for a nonmagnetic layer are known as magnetoresistive elements. The magnetoresistive elements can be applied to magnetic sensors, high-frequency parts, magnetic heads, and nonvolatile random-access memories (magnetoresistive random-access memories (MRAMs)).

An MRAM is a storage element into which magnetoresistive elements are integrated. In the MRAM, data is read and written using characteristics in which resistance of a magnetoresistive element changes when a direction of the mutual magnetization of two ferromagnetic layers sandwiching a nonmagnetic layer in a magnetoresistive element changes. A direction of magnetization of the ferromagnetic layer, for example, is controlled using a magnetic field generated by an electric current. Moreover, for example, the direction of the magnetization of the ferromagnetic layer is controlled using spin transfer torque (STT) generated by causing an electric current to flow in a lamination direction of the magnetoresistive elements.

When the direction of the magnetization of the ferromagnetic layer is rewritten using the STT, the electric current flows in a lamination direction of the magnetoresistive elements. A write current causes deterioration in characteristics of the magnetoresistive element.

In recent years, attention has been focused on a method in which an electric current does not need to flow in a lamination direction of magnetoresistive elements at the time of writing (for example, Patent Document 1). One method is a writing method using spin-orbit torque (SOT). The SOT is induced by a spin current caused by spin-orbit interaction or a Rashba effect at an interface between dissimilar materials. An electric current for inducing the SOT in the magnetoresistive element flows in a direction intersecting the lamination direction of the magnetoresistive elements. That is, an electric current does not need to flow in a lamination direction of magnetoresistive elements and it is expected to extend the lifespan of the magnetoresistive element.

### CITATION LIST

### Patent Document

### [Patent Document 1]

Japanese Unexamined Patent Application, First Publication No. 2017-216286

### SUMMARY OF INVENTION

### Technical Problem

A magnetic memory has a plurality of magnetoresistive elements that are integrated. As an amount of electric current applied to each magnetoresistive element increases, the power consumption of the magnetic memory increases. It is necessary to decrease the amount of electric current to be applied to each magnetoresistive element and to suppress the power consumption of the magnetic memory.

On the other hand, in the case of a magnetoresistive element using spin-orbit torque (SOT), if a resistance value of the spin-orbit torque wiring through which the write current flows is excessively large, a magnetoresistance (MR) ratio of the magnetoresistive element becomes low or heat generation is likely to occur when the write current is applied.

An objective of the present invention is to provide a magnetized rotary element, a magnetoresistive element, and a magnetic memory that can operate with a small electric current and have a high MR ratio.

### Solution to Problem

The present invention provides the following means to solve the above-described problems.

(1) According to a first aspect, a magnetized rotary element includes spin-orbit torque wiring; and a first ferromagnetic layer connected to the spin-orbit torque wiring. The spin-orbit torque wiring includes a topological insulator in which electrical conductors are dispersed.

(2) In the magnetized rotary element according to the above-described aspect, the spin-orbit torque wiring may have a first region and a second region. The first region internally includes an electrical conductor and the second region internally includes no electrical conductor.

(3) In the magnetized rotary element according to the above-described aspect, the second region may be located further away from the first ferromagnetic layer than the first region.

(4) In the magnetized rotary element according to the above-described aspect, the first region and the second region are arranged in a lamination direction.

(5) In the magnetized rotary element according to the above-described aspect, the spin-orbit torque wiring may have a plurality of first regions internally including electrical conductors and one or more second regions internally including no electrical conductor. The second region is located between the first regions adjacent in a lamination direction.

(6) In the magnetized rotary element according to the above-described aspect, the first region may be in contact with the first ferromagnetic layer.

(7) The magnetized rotary element according to the above-described aspect may further include an amorphous layer on an opposite side of the first ferromagnetic layer on the basis of the spin-orbit torque wiring.

(8) In the magnetized rotary element according to the above-described aspect, the amorphous layer may include any one metal selected from the group consisting of Ti, Cr, Ta, W, Au, and Ni.

(9) According to a second aspect, a magnetoresistive element includes the magnetized rotary element according to the above-described aspect; a second ferromagnetic layer; and a nonmagnetic layer. The nonmagnetic layer is sandwiched between the first ferromagnetic layer and the second ferromagnetic layer.

(10) According to a third aspect, a magnetic memory includes a plurality of magnetoresistive elements according to the above-described aspect.

### Advantageous Effects of Invention

According to the present invention, a magnetized rotary element, a magnetoresistive element, and a magnetic memory can operate with a small electric current and have a high MR ratio.

### BRIEF DESCRIPTION OF DRAWINGS

FIG. 1 is a circuit diagram of a magnetic memory according to a first embodiment.

FIG. 2 is a cross-sectional view of featured parts of the magnetic memory according to the first embodiment.

FIG. 3 is a cross-sectional view of a magnetoresistive element according to the first embodiment.

FIG. 4 is a top view of the magnetoresistive element according to the first embodiment.

FIG. 5 is a cross-sectional view of a magnetoresistive element according to a first modified example.

FIG. 6 is a cross-sectional view of a magnetoresistive element according to a second modified example.

FIG. 7 is a cross-sectional view of a magnetoresistive element according to a third modified example.

FIG. 8 is a cross-sectional view of a magnetoresistive element according to a fourth modified example.

FIG. 9 is a cross-sectional view of a magnetized rotary element according to a second embodiment.

### DESCRIPTION OF EMBODIMENTS

Hereinafter, embodiments will be described in detail with reference to the drawings as appropriate. In the drawings used in the following description, featured parts may be enlarged for convenience such that the features of the present invention are easier to understand, and dimensional ratios and the like of the respective constituent elements may be different from actual ones. Materials, dimensions, and the like exemplified in the following description are examples, the present invention is not limited thereto, and modifications can be appropriately made in a range in which advantageous effects of the present invention are exhibited.

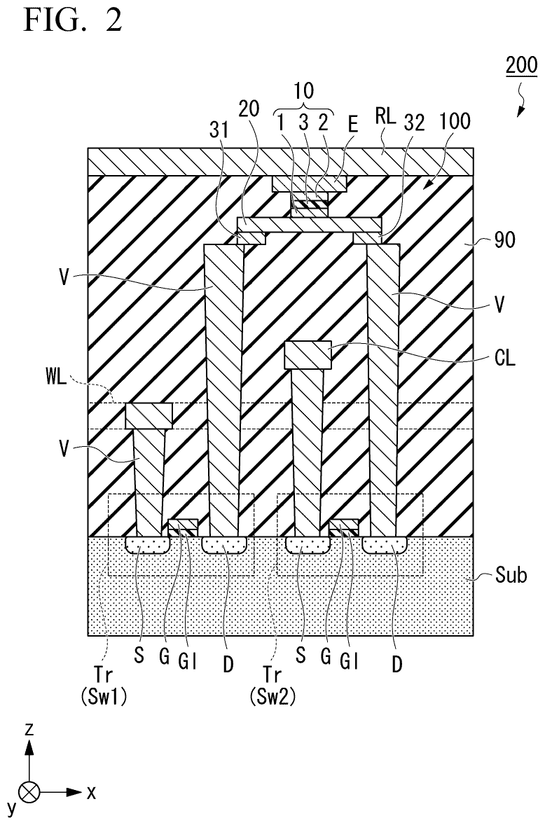

First, directions will be defined. A direction of one surface of a substrate Sub (see, for example, FIG. 2) to be described below is defined as an x-direction and a direction perpendicular to the x-direction is defined as a y-direction. The x-direction is, for example, a longitudinal direction of spin-orbit torque wiring 20. A z-direction is a direction perpendicular to the x-direction and the y-direction. The z-direction is an example of a lamination direction in which layers are laminated. A +z-direction may be expressed as an “upward direction” and a −z-direction may be expressed as a “downward direction.” The upward/downward direction does not necessarily coincide with a direction in which gravity is applied.

In the present specification, “extending in the x-direction” indicates, for example, that a dimension in the x-direction is larger than a minimum dimension among dimensions in the x-direction, the y-direction, and the z-direction. The same is true for the case of extending in another direction. Moreover, the term “connection” in the present specification is not limited to a physical connection. For example, the term “connection” is not limited to a case where two layers are physically in contact and also includes a case where two layers are connected by sandwiching another layer between the two layers. Moreover, the term “connection” in the present specification includes an electrical connection.

### First Embodiment

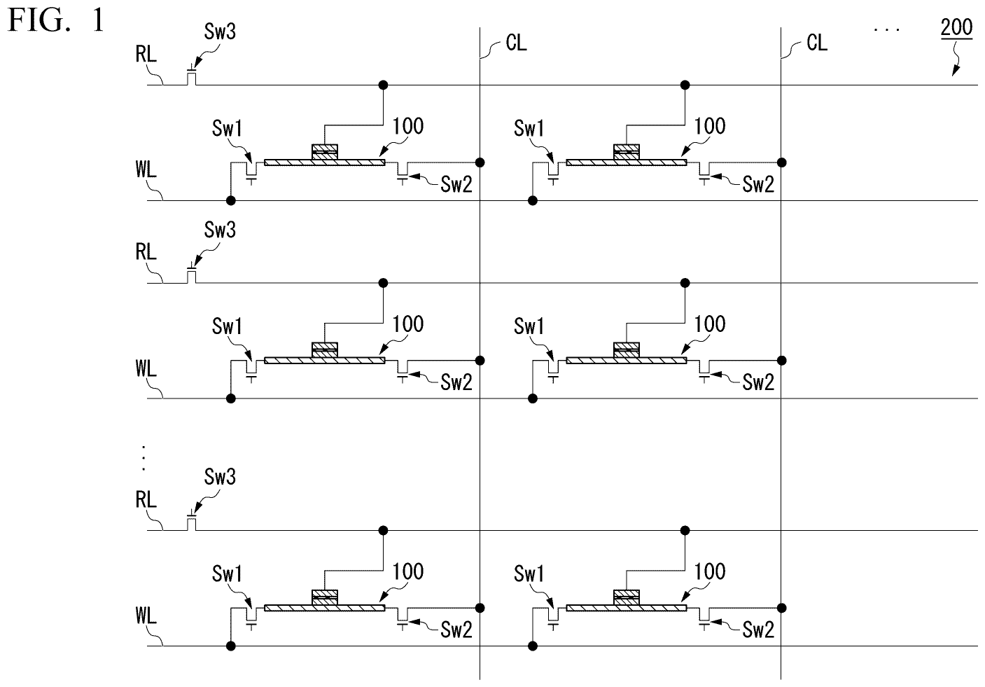

FIG. 1 is a configuration diagram of a magnetic memory 200 according to a first embodiment. The magnetic memory 200 includes a plurality of magnetoresistive elements 100, a plurality of write wirings WL, a plurality of common wirings CL, a plurality of read wirings RL, a plurality of first switching elements Sw1, a plurality of second switching elements Sw2, and a plurality of third switching elements Sw3. In the magnetic memory 200, for example, the magnetoresistive elements 100 are arranged in a matrix.

The write wiring WL electrically connects a power supply to one or more magnetoresistive elements 100. The common wiring CL is wiring for use at both the time when data is written and the time when data is read. The common wiring CL electrically connects a reference potential to one or more magnetoresistive elements 100. The reference potential is, for example, a ground potential. The common wiring CL may be provided in each of the plurality of magnetoresistive elements 100 or may be provided across the plurality of magnetoresistive elements 100. The read wiring RL electrically connects the power supply to one or more magnetoresistive elements 100. The power supply is connected to the magnetic memory 200 when in use.

Each magnetoresistive element 100 is connected to the first switching element Sw1, the second switching element Sw2, and the third switching element Sw3. The first switching element Sw1 is connected between the magnetoresistive element 100 and the write wiring WL. The second switching element Sw2 is connected between the magnetoresistive element 100 and the common wiring CL. The third switching element Sw3 is connected to the read wiring RL across the plurality of magnetoresistive elements 100.

When a predetermined first switching element Sw1 and a predetermined second switching element Sw2 are turned on, a write current flows between the write wiring WL and the common wiring CL connected to a predetermined magnetoresistive element 100. The write current flows, and therefore data is written to the predetermined magnetoresistive element 100. When a predetermined second switching element Sw2 and a predetermined third switching element Sw3 are turned on, a read current flows between the common wiring CL and the read wiring RL connected to the predetermined magnetoresistive element 100. The read current flows, and therefore data is read from the predetermined magnetoresistive element 100.

The first switching element Sw1, the second switching element Sw2, and the third switching element Sw3 are elements that control a flow of an electric current. The first switching element Sw1, the second switching element Sw2, and the third switching element Sw3 are, for example, a transistor, an element using a change in a crystal layer phase like an ovonic threshold switch (OTS), an element using a change in a band structure like a metal insulator transition (MIT) switch, an element using a breakdown voltage like a Zener diode and an avalanche diode, and an element whose conductivity changes with a change in an atomic position.

In the magnetic memory 200 shown in FIG. 1, the magnetoresistive elements 100 connected to the same read wiring RL share the third switching element Sw3. The third switching element Sw3 may be provided in each magnetoresistive element 100. Moreover, the third switching element Sw3 is provided in each magnetoresistive element 100 and the first switching element Sw1 or the second switching element Sw2 may be shared by the magnetoresistive elements 100 connected to the same wiring.

FIG. 2 is a cross-sectional view of featured parts of the magnetic memory 200 according to the first embodiment. FIG. 2 shows a cross-section obtained by cutting the magnetoresistive element 100 in an xz-plane passing through the center of a width of the spin-orbit torque wiring 20 in the y-direction to be described below.

The first switching element Sw1 and the second switching element Sw2 shown in FIG. 2 are transistors Tr. The third switching element Sw3 is electrically connected to the read wiring RL and is located at a different position in the x-direction of FIG. 2. The transistor Tr is, for example, a field-effect type transistor, and includes a gate electrode G, a gate insulating film GI, and a source S and a drain D formed on the substrate Sub. The source S and the drain D are defined according to a direction of an electric current flow and they are in the same region. A positional relationship between the source S and the drain D may be reversed. The substrate Sub is, for example, a semiconductor substrate.

The transistor Tr and the magnetoresistive element 100 are electrically connected via wiring V, the first electrode 31, and the second electrode 32. Moreover, the transistor Tr and the write wiring WL or the common wiring CL are connected by the via wiring V. The via wiring V, for example, extends in the z-direction. The read wiring RL is connected to the laminate 10 via an electrode E. The via wiring V and the electrode E include a material having electrical conductivity. The via wiring V and the first electrode 31 may be integrated. Moreover, the via wiring V and the second electrode 32 may be integrated. That is, the first electrode 31 may be a part of the via wiring V and the second electrode 32 may be a part of the via wiring V.

The periphery of the magnetoresistive element 100 and the transistor Tr is covered with an insulating layer 90. The insulating layer 90 is an insulating layer that insulates between wirings of multilayer wiring or between elements. The insulating layer 90 is, for example, silicon oxide (SiOₓ), silicon nitride (SiNₓ), silicon carbide (SiC), chromium nitride, silicon carbon nitride (SiCN), silicon oxynitride (SiON), aluminum oxide (Al₂O₃), zirconium oxide (ZrOx), magnesium oxide (MgO), aluminum nitride (AlN), or the like.

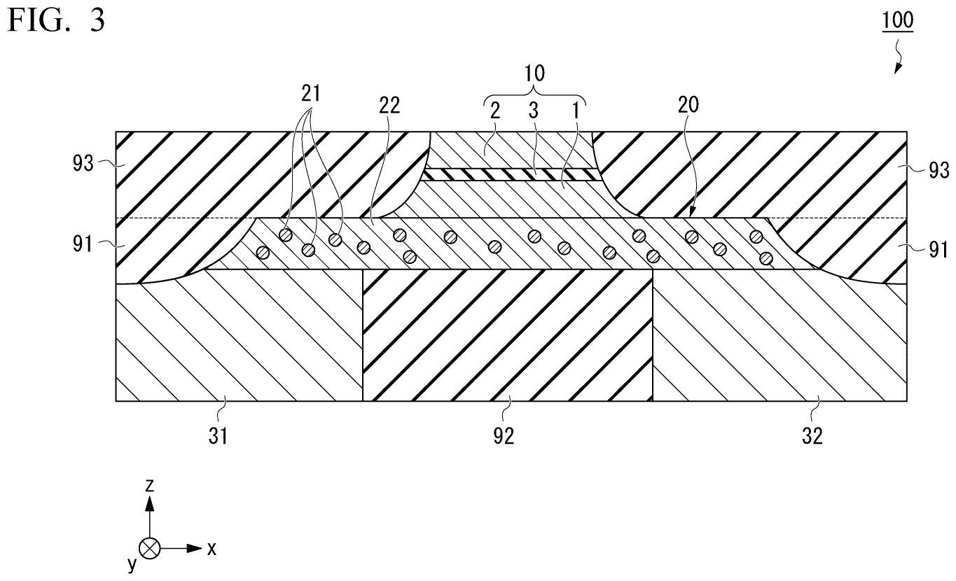

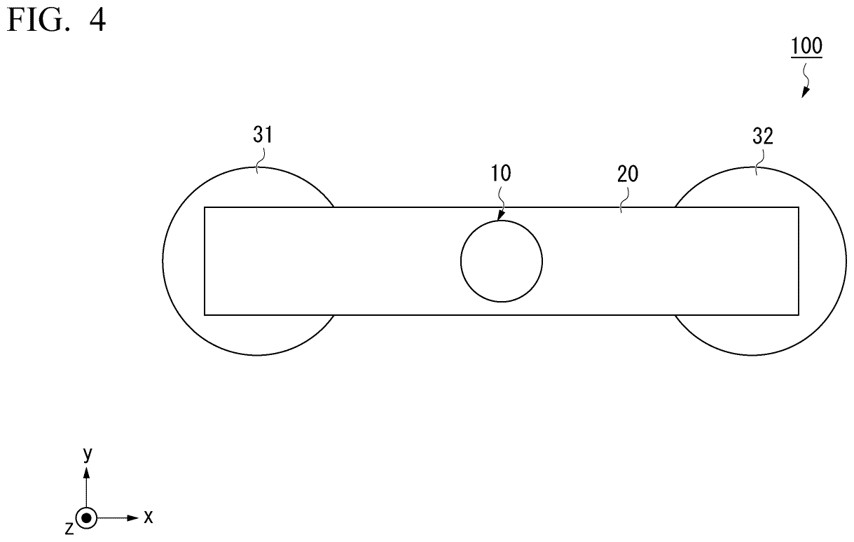

FIG. 3 is a cross-sectional view of the magnetoresistive element 100. FIG. 3 shows a cross-section obtained by cutting the magnetoresistive element 100 in the xz-plane passing through the center of the width of the spin-orbit torque wiring 20 in the y-direction. FIG. 4 is a top view of the magnetoresistive element 100 seen from the z-direction.

The magnetoresistive element 100 includes, for example, a laminate 10, a spin-orbit torque wiring 20, a first electrode 31, and a second electrode 32. The laminate 10 includes a first ferromagnetic layer 1, a second ferromagnetic layer 2, and a nonmagnetic layer 3.

The periphery of the magnetoresistive element 100 is covered, for example, with a first insulating layer 91, a second insulating layer 92, and a third insulating layer 93. The first insulating layer 91, the second insulating layer 92, and the third insulating layer 93 are parts of the insulating layer 90 described above. The first insulating layer 91 is in the same layer as the spin-orbit torque wiring 20. The second insulating layer 92 is at the same level as the first electrode 31 and the second electrode 32. The third insulating layer 93 is in the same layer as the laminate 10.

The magnetoresistive element 100 may be a magnetic element using spin-orbit torque (SOT) and may be referred to as a spin-orbit torque type magnetoresistive element, a spin injection type magnetoresistive element, or a spin current magnetoresistive element.

The magnetoresistive element 100 is an element that records and stores data. The magnetoresistive element 100 records data at a resistance value of the laminate 10 in the z-direction. The resistance value of the laminate 10 in the z-direction is changed by applying a write current along the spin-orbit torque wiring 20 and injecting spin from the spin-orbit torque wiring 20 to the laminate 10. The resistance value of the laminate 10 in the z-direction can be read by applying a read current of the laminate 10 in the z-direction.

The first electrode 31 and the second electrode 32 are connected to the spin-orbit torque wiring 20 at a position where the first ferromagnetic layer 1 is sandwiched when seen from the z-direction. There may be other layers between the first electrode 31 and the spin-orbit torque wiring 20 and between the second electrode 32 and the spin-orbit torque wiring 20.

The first electrode 31 and the second electrode 32 are, for example, conductors that electrically connect the switching element and the magnetoresistive element 100. Both the first electrode 31 and the second electrode 32 are electrically conductive.

For example, the length of the spin-orbit torque wiring 20 in the x-direction is longer than in the y-direction as seen from the z-direction and extends in the x-direction. The write current flows in the x-direction between the first electrode 31 and the second electrode 32 along the spin-orbit torque wiring 20. The spin-orbit torque wiring 20 is connected to each of the first electrode 31 and the second electrode 32.

The spin-orbit torque wiring 20 generates a spin current with a spin Hall effect when an electric current flows and injects spin into the first ferromagnetic layer 1. The spin-orbit torque wiring 20, for example, applies spin-orbit torque (SOT) sufficient to reverse the magnetization of the first ferromagnetic layer 1 to the magnetization of the first ferromagnetic layer 1. The spin Hall effect is a phenomenon in which the spin current is induced in a direction orthogonal to a direction in which the electric current flows on the basis of the spin-orbit interaction when the electric current flows. The spin Hall effect is similar to the normal Hall effect in that the motion (moving) charge (electrons) can be curve in a motion (movement) direction. In the normal Hall effect, a direction of motion of charged particles moving in a magnetic field is curve by a Lorentz force. On the other hand, in the spin Hall effect, even if there is no magnetic field, a spin movement direction is curve only by the movement of electrons (only by the flow of an electric current).

For example, when an electric current flows through the spin-orbit torque wiring 20, the first spin polarized in one direction and the second spin polarized in a direction opposite to the first spin are curve by the spin Hall effect in a direction perpendicular to the direction in which the electric current flows. For example, the first spin polarized in the −y-direction is curve in the +z-direction from the x-direction, which is a travel direction, and the second spin polarized in the +y-direction is curve in the −z-direction from the x-direction, which is the travel direction.

In nonmagnetic materials (nonferromagnetic materials), the number of electrons in the first spin and the number of electrons in the second spin, which is caused by the spin Hall effect are equal. That is, the number of electrons in the first spin in the +z-direction is equal to the number of electrons in the second spin in the −z-direction. The first and second spins flow in a direction in which the uneven distribution of spin is eliminated. Because flows of charge are offset by each other in the movements of the first and second spins in the z-direction, the amount of electric current becomes zero. spin current without any electric current is specifically referred to as a pure spin current.

If the flow of electrons in the first spin is denoted by J_{↑}, the flow of electrons in the second spin is denoted by J_{↓}, and the spin current is denoted by J_{S}, J_{S}=J_{↑}−J_{↓} is defined. The spin current J_{S} occurs in the z-direction. The first spin is injected into the first ferromagnetic layer 1 from the spin-orbit torque wiring 20.

The spin-orbit torque wiring 20 includes a topological insulator 22 in which electrical conductors 21 are dispersed. The spin-orbit torque wiring 20 has, for example, a granular structure. The granular structure is a structure in which nanoscale electrical conductors are densely dispersed in an insulator. In the spin-orbit torque wiring 20, the electrical conductors 21 are densely dispersed in the matrix of the topological insulator 22. The electrical conductors 21 are separated from each other by the topological insulator 22. Between the electrical conductors 21, electronic conduction occurs due to the tunnel effect of electrons.

The topological insulator 22 is a substance in which the inside of the substance is an insulator or a high resistive material, but a spin-polarized metallic state is on the surface. The topological insulator 22 generates an internal magnetic field due to spin-orbit interaction. In the topological insulator 22, a new topological phase is expressed by the effect of spin-orbit interaction even in the absence of an external magnetic field. Topological insulators can generate a pure spin current with high efficiency due to strong spin-orbit interactions and the breaking of inversion symmetry at the edges.

The topological insulator 22 is, for example, SnTe, B_{1.5}Sb_{0.5}Te_{1.7}Se_{1.3}, TlBiSe₂, Bi₂Te₃, Bi₁₋ₓSbₓ, (Bi₁₋ₓSbₓ)₂Te₃, or the like. The topological insulator 22 may be, for example, an oxide of a pyrochlore structure represented by the composition formula R₂Ir₂O₇. R in the composition formula is one or more elements selected from the group consisting of Pr, Nd, Sm, Eu, Gd, Tb, Dy, and Ho.

The electrical conductor 21 is a metal, oxide, or the like having electrical conductivity. The electrical conductor 21 is, for example, Mg, Al, Tl, Fe, Cr, W, Pd, Au, Ag, Ta, Ir, Pt, Cu, Mo, Ru, Zr, or an oxide thereof. The electrical conductor 21 is preferably a metal from the viewpoint of reducing the electrical resistivity of the spin-orbit torque wiring and suppressing a decrease in the MR ratio. When the topological insulator is an oxide, the electrical conductor 21 is oxidized in the formation process and the electrical resistivity is likely to increase. From the viewpoint of lowering the electrical resistivity even in the oxidized state, it is preferable to be a conductive oxide. The electrical conductor 21 may be, for example, a nonmagnetic material or a magnetic material.

When the electrical conductor 21 is a magnetic material, a small amount of magnetic metal becomes a scattering factor for spin. The small amount is, for example, 3% or less of the total molar ratio of the elements constituting the spin-orbit torque wiring 20. When the spin is scattered by the magnetic metal, the spin-orbit interaction is enhanced and the spin current generation efficiency for the electric current is increased.

The electrical resistivity of the spin-orbit torque wiring 20 is, for example, 1 mΩ·cm or more. Moreover, the electrical resistivity of the spin-orbit torque wiring 20 is, for example, 10 mΩ·cm or less. When the electrical resistivity of the spin-orbit torque wiring 20 is high, a high voltage can be applied to the spin-orbit torque wiring 20. When the potential of the spin-orbit torque wiring 20 becomes high, spin can be efficiently supplied from the spin-orbit torque wiring 20 to the first ferromagnetic layer 1. Moreover, when the spin-orbit torque wiring 20 has a certain electrical conductivity level or higher, an electric current path flowing along the spin-orbit torque wiring 20 can be secured and a spin current associated with the spin Hall effect can be efficiently generated.

The thickness of the spin-orbit torque wiring 20 is, for example, 4 nm or more. The thickness of the spin-orbit torque wiring 20 may be, for example, 20 nm or less.

The laminate 10 is connected to the spin-orbit torque wiring 20. The laminate 10 is laminated, for example, on the spin-orbit torque wiring 20. Another layer may be provided between the laminate 10 and the spin-orbit torque wiring 20.

The resistance value of the laminate 10 in the z-direction changes when spin is injected into the laminate 10 (the first ferromagnetic layer 1) from the spin-orbit torque wiring 20.

The laminate 10 is sandwiched between the spin-orbit torque wiring 20 and the electrode E (see FIG. 2) in the z-direction. The laminate 10 is a columnar body. The planar view shape of the laminate 10 from the z-direction is, for example, a round, an oval, or a square. The side surface of the laminate 10 is inclined with respect to, for example, the z-direction.

The laminate 10 includes, for example, a first ferromagnetic layer 1, a second ferromagnetic layer 2, and a nonmagnetic layer 3. The first ferromagnetic layer 1, for example, is in contact with the spin-orbit torque wiring 20 and is laminated on the spin-orbit torque wiring 20. Spin is injected into the first ferromagnetic layer 1 from the spin-orbit torque wiring 20. The magnetization of the first ferromagnetic layer 1 receives spin-orbit torque (SOT) due to the injected spin and an orientation direction changes. The first ferromagnetic layer 1 and the second ferromagnetic layer 2 sandwich the nonmagnetic layer 3 in the z-direction.

Each of the first ferromagnetic layer 1 and the second ferromagnetic layer 2 has magnetization. The magnetization of the second ferromagnetic layer 2 is less likely to change the orientation direction than the magnetization of the first ferromagnetic layer 1 when a predetermined external force is applied. The first ferromagnetic layer 1 may be referred to as a magnetized free layer and the second ferromagnetic layer 2 may be referred to as a magnetized fixing layer or a magnetized reference layer. In the laminate 10 shown in FIG. 3, the magnetized fixing layer is on the side away from the substrate Sub and is referred to as a top pin structure. The resistance value of the laminate 10 changes with a difference in a relative angle of magnetization between the first ferromagnetic layer 1 and the second ferromagnetic layer 2 sandwiching the nonmagnetic layer 3.

The first ferromagnetic layer 1 and the second ferromagnetic layer 2 include ferromagnetic material. The ferromagnetic material is, for example, a metal selected from the group consisting of Cr, Mn, Co, Fe, and Ni, an alloy containing one or more of these metals, an alloy containing at least one or more elements of B, C, and N, or the like. Ferromagnetic material are, for example, Co—Fe, Co—Fe—B, Ni—Fe, Co—Ho alloys, Sm—Fe alloys, Fe—Pt alloys, Co—Pt alloys, and CoCrPt alloys.

The first ferromagnetic layer 1 and the second ferromagnetic layer 2 may include a Heusler alloy. The Heusler alloy is an intermetallic compound having a chemical composition of XYZ or X₂YZ, wherein X is a transition metal element or a noble metal element of the Co. Fe, Ni, or Cu group on the periodic table, Y is a transition metal of the Mn, V, Cr, or Ti group or an elemental species of X, and Z is a typical element of Group III to Group V. Examples of the Heusler alloy include Co₂FeSi, Co₂FeGe, Co₂FeGa, Co₂MnSi, Co₂Mn₁₋ₐFeₐAl_{b}Si_{1-b}, Co₂FeGe_{1-c}Ga_{c}, and the like. The Heusler alloy has high spin polarizability.

The nonmagnetic layer 3 includes a nonmagnetic material. When the nonmagnetic layer 3 is an insulator (when it is a tunnel barrier layer), for example, Al₂O₃, SiO₂, MgO, MgAl₂O₄, and the like can be used as its material. Moreover, in addition to these, a material in which some of Al, Si, and Mg is replaced with Zn, Be, or the like can also be used. Among these, MgO and MgAl₂O₄ are materials that can implement a coherent tunnel, such that spin can be injected efficiently. When the nonmagnetic layer 3 is a metal, Cu, Au, Ag, or the like can be used as its material. Furthermore, when the nonmagnetic layer 3 is a semiconductor, Si, Ge, CuInSe₂, CuGaSe₂, Cu(In, Ga)Se₂, or the like can be used as its material.

The laminate 10 may have a layer other than the first ferromagnetic layer 1, the second ferromagnetic layer 2, and the nonmagnetic layer 3. For example, a base layer may be provided between the spin-orbit torque wiring 20 and the first ferromagnetic layer 1. The base layer increases the crystallinity of each layer constituting the laminate 10. Moreover, for example, a cap layer may be provided on the top surface of the laminate 10.

Moreover, in the laminate 10, a ferromagnetic layer may be provided via a spacer layer on a surface opposite to the nonmagnetic layer 3 of the second ferromagnetic layer 2. The second ferromagnetic layer 2, the spacer layer, and the ferromagnetic layer have a synthetic antiferromagnetic structure (SAF structure). The synthetic antiferromagnetic structure includes two magnetic layers sandwiching a nonmagnetic layer. When the second ferromagnetic layer 2 and the ferromagnetic layer are antiferromagnetically coupled, the coercivity of the second ferromagnetic layer 2 is greater than when no ferromagnetic layer is provided. The ferromagnetic layer is, for example, IrMn, PtMn, or the like. The spacer layer includes, for example, at least one selected from the group consisting of Ru, Ir, and Rh.

Next, a method of manufacturing the magnetoresistive element 100 will be described. The magnetoresistive element 100 is formed in a lamination step of each layer and a processing step in which a part of each layer is processed into a predetermined shape. For the lamination of each layer, a sputtering method, a chemical vapor deposition (CVD) method, an electron beam deposition method (EB deposition method), an atomic laser deposition method, or the like can be used. The processing of each layer can be performed using photolithography or the like.

First, impurities are doped at a predetermined position on the substrate Sub to form a source S and a drain D. Subsequently, a gate insulating film GI and a gate electrode G are formed between the source S and the drain D. The source S, the drain D, the gate insulating film GI, and the gate electrode G constitute a transistor Tr. The substrate Sub may use a commercially available semiconductor circuit board on which the transistor Tr is formed.

Subsequently, the insulating layer 90 is formed to cover the transistor Tr. Moreover, an opening is formed in the insulating layer 90 and the opening is filled with an electrical conductor, and therefore the via wiring V, the first electrode 31, and the second electrode 32 are formed. The write wiring WL and the common wiring CL are formed by laminating the insulating layer 90 to a predetermined thickness, forming a groove in the insulating layer 90, and filling the groove with an electrical conductor.

Subsequently, a layer serving as the spin-orbit torque wiring 20 is formed on one surface of the insulating layer 90, the first electrode 31, and the second electrode 32. For the spin-orbit torque wiring 20, for example, a step of growing the electrical conductors 21 into grains and a step of forming the topological insulator 22 can be separately performed.

First, in the step of growing particles of the electrical conductors 21, sputtering is performed, using the electrical conductors 21 as a target. In order to grow the electrical conductors 21 into grains, a degree of vacuum at the time of sputtering is lowered and the irradiation energy of ions is increased. If the energy of sputtering is large, atoms attached to a deposition surface can move, making it easier for grains to grow. Moreover, when the degree of vacuum is low, the electrical conductors 21 tend to grow grains. Moreover, the gas pressure in a deposition chamber may be increased to promote grain growth. The electrical conductors 21 that have grown the grains are scattered, for example, in the form of islands.

Subsequently, the topological insulator 22 is formed. A film of the topological insulator 22 can be formed in a sputtering method. For example, the film of the topological insulator 22 is formed to cover the electrical conductors 21 scattered in the form of islands. By covering the electrical conductors 21 scattered in the form of islands with the topological insulator 22, the topological insulator 22 in which the electrical conductors 21 are dispersed is obtained.

For example, if the step of growing the electrical conductors 21 into grains and the step of forming the topological insulator 22 are separately iterated a plurality of times, the electrical conductors 21 are dispersed throughout the inside of the spin-orbit torque wiring 20.

Subsequently, a ferromagnetic layer, a nonmagnetic layer, a ferromagnetic layer, and a hard mask layer are sequentially laminated on the layer serving as the spin-orbit torque wiring 20. Subsequently, the hard mask layer is processed into a predetermined shape. The predetermined shape is, for example, an external form of the spin-orbit torque wiring 20. Subsequently, the layer serving as the spin-orbit torque wiring 20, the ferromagnetic layer, the nonmagnetic layer, and the ferromagnetic layer are processed into a predetermined shape at once via the hard mask layer.

Subsequently, an unnecessary portion of the hard mask layer in the x-direction is removed. The hard mask layer is an external form of the laminate 10. Subsequently, an unnecessary portion of the laminate in the x-direction formed on the spin-orbit torque wiring 20 is removed via the hard mask layer. The laminate 10 is processed into a predetermined shape. The hard mask layer becomes the electrode E. Subsequently, the periphery of the laminate 10 and the spin-orbit torque wiring 20 is filled with the insulating layer 90 to obtain the magnetoresistive element 100.

The magnetoresistive element 100 according to the first embodiment can operate with a small electric current and have a high MR ratio because the spin-orbit torque wiring 20 includes the topological insulator 22 in which the electrical conductors 21 are dispersed.

This is because the electrical conductor 21 assists electronic conduction in the topological insulator 22, and therefore the electronic conductivity of the spin-orbit torque wiring 20 is appropriate.

The topological insulator 22 has resistance that is at least three times higher than that of a high-resistance metal such as tungsten. Therefore, the spin-orbit torque wiring 20 including the topological insulator 22 can apply a high voltage and the first ferromagnetic layer 1 can be injected with a large amount of spin.

On the other hand, if the resistance of the spin-orbit torque wiring 20 is too high, the resistance value of the base of the magnetoresistive element 100 becomes larger and the MR ratio decreases.

The MR ratio of the magnetoresistive element 100 is expressed by the following relation equation.

MR ratio (%)=(R_{AP}−R_{P})/R_{P}×100

R_{P} denotes a resistance value of the magnetoresistive element 100 in the lamination direction when the magnetization directions of the first ferromagnetic layer 1 and the second ferromagnetic layer 2 are parallel and R_{AP} denotes a resistance value of the magnetoresistive element 100 in the lamination direction when the magnetization directions of the first ferromagnetic layer 1 and the second ferromagnetic layer 2 are antiparallel.

The base resistance has a resistance value when the magnetization directions of the first ferromagnetic layer 1 and the second ferromagnetic layer 2 are parallel and the MR ratio of the magnetoresistive element 100 decreases if the denominator of the above equation increases.

In the magnetoresistive element 100 according to the present embodiment, the topological insulator 22 is the main constituent element of the spin-orbit torque wiring 20, and can apply a high voltage and the spin injection efficiency to the first ferromagnetic layer 1 can be increased. Moreover, because the magnetoresistive element 100 according to the present embodiment assists electronic conduction in the electrical conductor 21, the MR ratio of the magnetoresistive element 100 can be prevented from becoming small.

Although an example of the magnetoresistive element 100 according to the first embodiment has been described above, additions, omissions, substitutions, and other modifications of the configuration can be made without departing from the spirit or scope of the present invention.

### First Modified Example

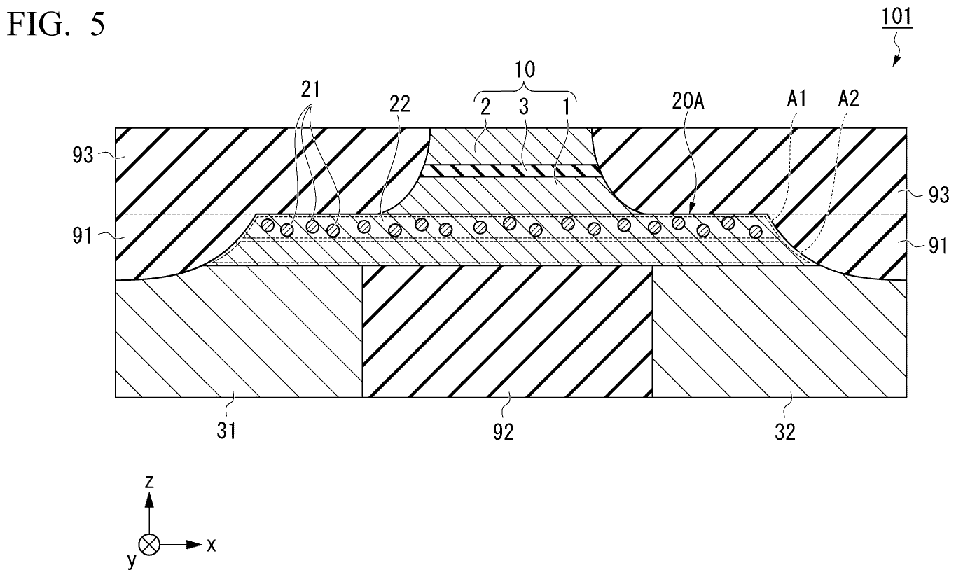

FIG. 5 is a cross-sectional view of a magnetoresistive element 101 according to a first modified example. FIG. 5 is an xz-cross-section passing through the center of spin-orbit torque wiring 20A in the y-direction. Constituent elements in FIG. 5 identical to those in FIG. 3 are denoted by similar reference signs and description thereof will be omitted.

Unlike the magnetoresistive element 100, the magnetoresistive element 101 according to the first modified example has a configuration of the spin-orbit torque wiring 20A.

The spin-orbit torque wiring 20A includes a first region A1 and a second region A2. The first region A1 internally includes electrical conductors 21. The second region A2 internally includes no electrical conductor 21. The first region A1 is, for example, a topological insulator 22 in which electrical conductors 21 are included. The second region A2 is, for example, a topological insulator 22 in which no electrical conductor 21 is included. The second region A2 may be a region other than the topological insulator 22 if it includes no electrical conductor 21.

The first region A1 and the second region A2 are arranged, for example, in a lamination direction (z-direction). The first region A1 is, for example, a region between an xy-plane passing through the top of the electrical conductors 21 in the spin-orbit torque wiring 20A and an xy-plane passing through the bottom of the electrical conductors 21. The second region A2 is located further away from a first ferromagnetic layer 1 than the first region A1. The first region A1 is, for example, in contact with the first ferromagnetic layer 1.

The first region A1, for example, has higher electronic conductivity than the second region A2. In this case, when an electric current passes through the spin-orbit torque wiring 20A, a current shunt ratio for the first region A1 is higher than a current shunt ratio for the second region A2. By arranging the first region A1 through which a large amount of electric current flows, in the vicinity of the first ferromagnetic layer 1, the magnetization reversal of the first ferromagnetic layer 1 can be made easier.

The magnetoresistive element 101 according to the first modified example can have an effect similar to that of the magnetoresistive element 100 according to the first embodiment.

### Second Modified Example

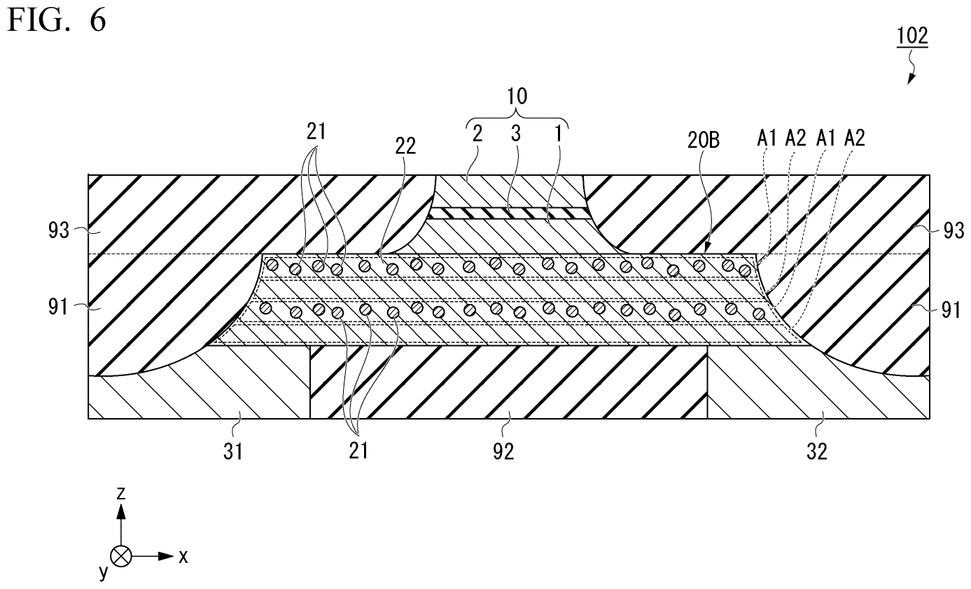

FIG. 6 is a cross-sectional view of a magnetoresistive element 102 according to a second modified example. FIG. 6 is an xz-cross-section passing through the center of spin-orbit torque wiring 20B in the y-direction. Constituent elements in FIG. 6 identical to those in FIG. 3 are denoted by similar reference signs and description thereof will be omitted.

Unlike the magnetoresistive element 101, the magnetoresistive element 102 according to the second modified example has a configuration of the spin-orbit torque wiring 208.

The spin-orbit torque wiring 20B includes a plurality of first regions A1 and a plurality of second regions A2. The second region A2 is between the adjacent first regions A1. When the first regions A1 and the second regions A2 are alternately laminated, an interface increases in the spin-orbit torque wiring 20B. When the number of different interfaces increases inside, an amount of spin injection from the spin-orbit torque wiring 20B to a first ferromagnetic layer 1 increases due to a Rashba effect.

The magnetoresistive element 102 according to the second modified example can have an effect similar to that of the magnetoresistive element 100 according to the first embodiment.

### Third Modified Example

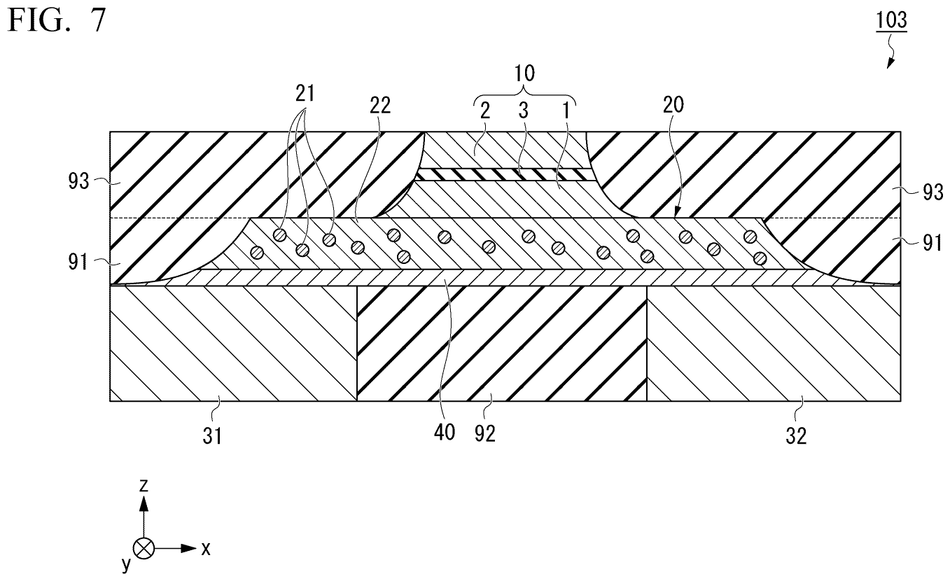

FIG. 7 is a cross-sectional view of a magnetoresistive element 103 according to a third modified example. FIG. 7 is an xz-cross-section passing through the center of spin-orbit torque wiring 20 in the y-direction. Constituent elements in FIG. 7 identical to those in FIG. 3 are denoted by similar reference signs and description thereof will be omitted.

Unlike the magnetoresistive element 100, the magnetoresistive element 103 according to the third modified example has an amorphous layer 40.

The amorphous layer 40 is, for example, a base layer of the spin-orbit torque wiring 20. The amorphous layer 40 is, for example, Ti, Cr, Ta, Au, or Ni.

The amorphous layer 40, for example, can prevent the crystal lattices of a second insulating layer 92, a first electrode 31, and a second electrode 32 from affecting the crystal lattices of the spin-orbit torque wiring 20. The amorphous layer 40 increases the flatness of a lamination surface of the spin-orbit torque wiring 20 and a laminate 10.

The magnetoresistive element 103 according to the third modified example can have an effect similar to that of the magnetoresistive element 100 according to the first embodiment. Moreover, the magnetoresistive element 102 has the amorphous layer 40, and therefore a lamination surface of the laminate 10 is flattened. When the lamination surface of the laminate 10 becomes flat, a magnetic resistance change rate (MR ratio) of the laminate 10 increases.

### Fourth Modified Example

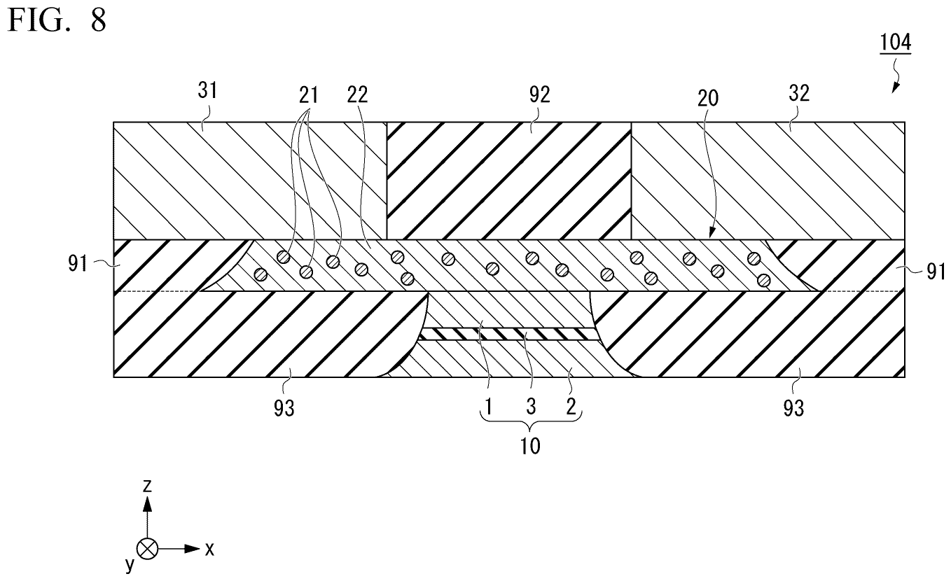

FIG. 8 is a cross-sectional view of a magnetoresistive element 104 according to a fourth modified example. FIG. 8 is an xz-cross-section passing through the center of spin-orbit torque wiring 20 in the y-direction. Constituent elements in FIG. 8 identical to those in FIG. 3 are denoted by similar reference signs and description thereof will be omitted.

A laminate 10 shown in FIG. 8 has a bottom pin structure in which a magnetized fixing layer (second ferromagnetic layer 2) is located near a substrate Sub. When the magnetized fixing layer is on the substrate Sub side, the stability of the magnetization of the magnetized fixing layer is increased and an MR ratio of the magnetoresistive element 104 is increased. The spin-orbit torque wiring 20, for example, is on the laminate 10. A first electrode 31 and a second electrode 32 are on the spin-orbit torque wiring 20.

The magnetoresistive element 104 according to the fourth modified example is different only in the positional relationship of each configuration and can have an effect similar to that of the magnetoresistive element 100 according to the first embodiment.

### Second Embodiment

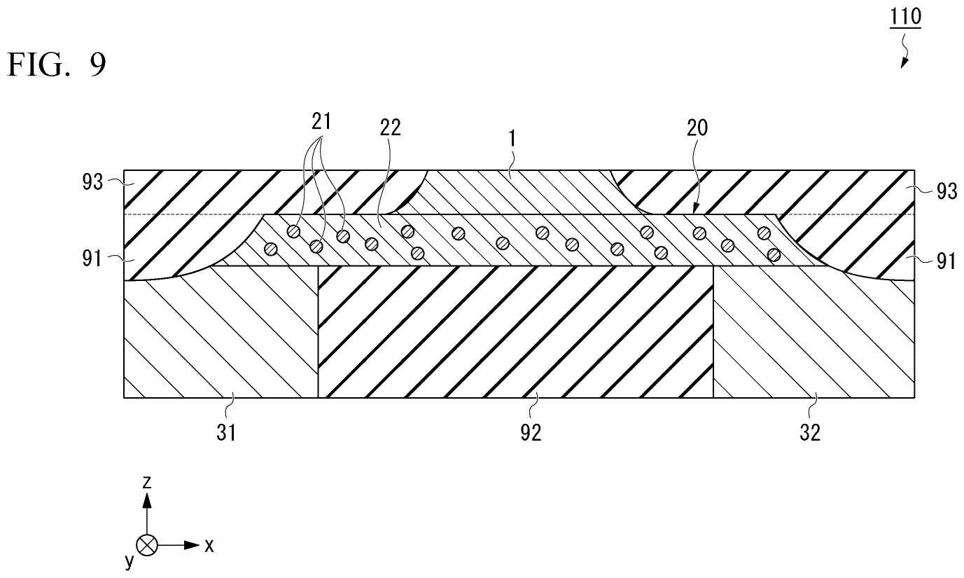

FIG. 9 is a cross-sectional view of a magnetized rotary element 110 according to a second embodiment. In FIG. 9, the magnetoresistive element 100 according to the first embodiment is replaced with the magnetized rotary element 110.

For example, the magnetized rotary element 110 applies light to a first ferromagnetic layer 1 and evaluates light reflected by the first ferromagnetic layer 1. When an orientation direction of magnetization changes due to a magnetic Kerr effect, a deflection state of the reflected light changes. The magnetized rotary element 110 can be used, for example, as an optical element such as a video display device using a difference in the deflection state of light.

In addition, the magnetized rotary element 110 can be used alone as an anisotropic magnetic sensor, an optical element using a magnetic Faraday effect, and the like.

Spin-orbit torque wiring 20 of the magnetized rotary element 110 includes a topological insulator 22 in which electrical conductors 21 are dispersed.

The magnetized rotary element 110 according to the second embodiment has a configuration in which only the nonmagnetic layer 3 and the second ferromagnetic layer 2 are excluded from the magnetoresistive element 100 and can have an effect similar to that of the magnetoresistive element 100 according to the first embodiment.

While examples of preferred aspects of the present invention have been described above on the basis of the first embodiment, the second embodiment, and the modified examples, the present invention is not limited to these embodiments. For example, the characteristic configurations in the embodiments and the modified examples may be applied to other embodiments and modified examples.

### REFERENCE SIGNS LIST

1 First ferromagnetic layer
2 Second ferromagnetic layer
3 Nonmagnetic layer
10 Laminate
20, 20A, 20B Spin-orbit torque wiring
21 Electrical conductor
22 Topological insulator
31 First electrode
32 Second electrode
40 Amorphous layer
90 Insulating layer
91 First insulating layer
92 Second insulating layer
93 Third insulating layer
100, 101, 102, 103, 104 Magnetoresistive element
110 Magnetized rotary element
200 Magnetic memory
A1 First region
A2 Second region
CL Common wiring
RL Read wiring
WL Write wiring

1. A magnetized rotary element comprising:
a spin-orbit torque wiring; and
a first ferromagnetic layer connected to the spin-orbit torque wiring,
wherein the spin-orbit torque wiring includes a topological insulator in which electrical conductors are dispersed.

2. The magnetized rotary element according to claim 1,
wherein the spin-orbit torque wiring has a first region and a second region,
wherein the first region internally includes an electrical conductor, and
wherein the second region internally includes no electrical conductor.

3. The magnetized rotary element according to claim 2, wherein the second region is located further away from the first ferromagnetic layer than the first region.

4. The magnetized rotary element according to claim 2, wherein the first region and the second region are laminated in a lamination direction.

5. The magnetized rotary element according to claim 2,
wherein the spin-orbit torque wiring has a plurality of first regions internally including electrical conductors and one or more second regions internally including no electrical conductor, and
wherein the second region is located between the first regions adjacent in a lamination direction.

6. The magnetized rotary element according to claim 2, wherein the first region is in contact with the first ferromagnetic layer.

7. The magnetized rotary element according to claim 1, further comprising an amorphous layer on an opposite side of the first ferromagnetic layer on the basis of the spin-orbit torque wiring.

8. The magnetized rotary element according to claim 7, wherein the amorphous layer includes any one metal selected from the group consisting of Ti, Cr, Ta, W, Au, and Ni.

9. A magnetoresistive element comprising:
the magnetized rotary element according to claim 1;
a second ferromagnetic layer; and
a nonmagnetic layer,
wherein the nonmagnetic layer is sandwiched between the first ferromagnetic layer and the second ferromagnetic layer.

10. A magnetic memory comprising a plurality of magnetoresistive elements according to claim 9.
